(19) United States
(12) Patent Application Publication
(10) Pub. No.: US 2012/0208313 A1
(43) Pub. Date: Aug. 16, 2012

(54) METHODS OF FORMING AGGREGATE PARTICLES OF NANOMATERIALS

(75) Inventors: Guozhong Cao, Seattle, WA (US); Qifeng Zhang, Seattle, WA (US); Junting Xi, Seattle, WA (US)

(73) Assignee: UNIVERSITY OF WASHINGTON, Seattle, WA (US)

(21) Appl. No.: 13/361,469

(22) Filed: Jan. 30, 2012

Related U.S. Application Data
(63) Continuation of application No. PCT/US2010/044012, filed on Jul. 30, 2010.
(60) Provisional application No. 61/230,141, filed on Jul. 31, 2009.
(60) Provisional application No. 61/275,082, filed on Aug. 25, 2009.
(60) Provisional application No. 61/251,999, filed on Oct. 15, 2009.

(51) Int. Cl. H01L 31/18; B05D 7/00; B29C 71/02; C01G 9/02; B29C 67/24; B05D 3/02; B82Y 30/00

(52) U.S. Cl. 438/71; 264/109; 427/180; 438/98; 423/622; 977/762; 977/773; 977/811; 257/E31.124; 257/E31.13

(57) ABSTRACT

Methods for forming aggregates of nanomaterials are provided. The aggregates are formed from a liquid dispersion of the nanomaterials in a liquid. The dispersion is aerosolized and the liquid removed from the aerosolized dispersion to provide the aggregates. The aggregates are useful as a photoelectric layer and/or a light-dispersive layer in dye-sensitized solar cells.

### CROSS-REFERENCES TO RELATED APPLICATIONS

This application is a continuation of PCT/US2010/044012, filed Jul. 30, 2010, which claims the benefit of U.S. Provisional Application No. 61/230,141, filed Jul. 31, 2009, U.S. Provisional Application No. 61/275,082, filed Aug. 25, 2009, and U.S. Provisional Application No. 61/251,999, filed Oct. 15, 2009, all of which are incorporated by reference herein, in their entirety, for any purpose.

### STATEMENT OF GOVERNMENT LICENSE RIGHTS

This invention was made with Government support under Grant No. DE-FG02-07ER46467, awarded by the Department of Energy, and under Grant No. FA9550-06-1-0326, awarded by the Air Force Office of Scientific Research. The Government has certain rights in the invention.

### FIELD OF THE INVENTION

This invention relates to the field of nanomaterials, more specifically to methods of producing aggregate particles of nanomaterials such as, but not limited to, titanium dioxide (TiO₂) and zinc oxide (ZnO), the compositions and structures of said aggregate particles, and the dye-sensitized solar cells incorporating said aggregate particles.

### BACKGROUND OF THE INVENTION

There is a growing interest in the development of next-generation photovoltaics, often referred to as the third generation solar technologies, not only because of their potential to significantly reduce the cost of photovoltaic devices, but also because of their superior performance to operate under variable lighting conditions over the conventional silicon-based photovoltaic technologies. Non-limiting examples of third generation solar technologies include dye-sensitized solar cells (DSCs) which have now reached commercial production. DSCs are known to maintain their efficiency to convert solar energy to electrical energy even under low light levels which makes DSCs ideal for indoor applications and direct integration into consumer electronics such as mobile phones.

Third generation solar technologies typically introduce nanostructures in the photovoltaic layers of solar cells by utilizing nanomaterials to improve the solar-to-electric power conversion efficiency (PCE) of photovoltaic devices. Nanomaterials are characterized by their sizes on the order of approximately 1 Angstrom to 100 μm and are available in a variety of structures including, but not limited to, nanoparticles, nanotubes, nanorods, nanowires, nanobelts, and nanoflowers. Recent advancements in nanotechnologies have lead to numerous high-performance products, including photovoltaic devices. Certain high-performance products comprise nanomaterials where the beneficial effects imparted by the nanomaterials result largely from the significantly higher surface area to volume ratio of the nanomaterials compared to bulk materials that are approximately 1 cm and above in size and whose chemical compositions are identical to those of the nanomaterials.

Among the third generation solar technologies, DSCs that use nanocrystalline TiO₂ as the photoelectrode material have demonstrated a solar-to-electric PCE of over 10% for the laboratory cells and 7-8% for modules. However, further improving the energy conversion efficiency of DSCs is still a challenge. For example and not limitation, the competition between the generation and recombination of photoexcited carriers in DSCs is a bottleneck that inhibits further increasing the solar-to-electric PCE. Accordingly, the design of DSCs may be improved by the development of technologies for enhancing the generation of photoexcited carriers in DSCs while minimizing the recombination of photoexcited carriers.

One possible solution for enhancing the generation of photoexcited carriers in DSCs, while minimizing the recombination of photoexcited carriers, is to increase the light-harvesting capability of the DSCs by introducing scatterers into the photoelectrode film. Recently, progress has been reported in ZnO DSCs by enhancing light scattering through a controlled aggregation of ZnO nanocrystallites. A PCE of 5.6% was achieved with laboratory cells using N3 dye (cis-bis-(4,4′-dicarboxy-2,2′-bipyridine)dithiocyanato ruthenium(II), Ru(dcbpy)₂ (NCS)₂), more than double the PCE in nanoporous ZnO electrode DSC (Zhang, Q. F.; Chou, T. R.; Russo, B.; Jenekhe, S. A.; Cao, G. Z. Angewandte Chemie-International Edition 2008, 47, 2402-2406: Chou, T. P.; Zhang, Q. F.; Fryxell, G. E.; Cao, G. Z. Advanced Materials 2007, 19, 2588-2592: Zhang, Q. F., Chou, T. P., Russo, B., Jenekhe, S. A., Cao, G. Z., Advanced Functional Materials 2008, 18, 1654-1660: Chou T. P., Zhang, Q. F., Cao, G. Z., Journal of Physical Chemistry C, 2007, 111, 18804-18811).

Superior performance of controlled aggregates of ZnO nanocrystallites over nanomaterials free of agglomeration can also be seen, for example, in the PCT application PCT/US09/52531 which discloses a DSC consisting of a photoelectrode comprising aggregates of ZnO nanoparticles. Similarly, superior performance of controlled aggregates of TiO₂ nanocrystallites over nanomaterials free of agglomeration can be seen in the PCT application PCT/US2010/038896 which discloses a DSC consisting of a photoelectrode comprising aggregates of TiO₂ nanoparticles or nanotubes.

The improvement in the PCE of DSC comprising the photoelectrodes of controlled aggregates results from the enhanced light scattering caused by the aggregates whose size is comparable to the wavelength of light. Photoelectrodes of controlled aggregates capture incident light more efficiently than photoelectrodes comprising nanomaterials free of agglomeration, while maintaining a very high surface area to volume ratio of photoelectrodes. In addition, improved light capturing by the photoelectrodes enables the reduction in the thickness of the photoelectrodes, thereby reducing the unwanted recombination of photogenerated electrons.

Although the aggregate particles of nanomaterials exhibit superior performance by improving the solar-to-electric PCE of DSCs, PCT/US09/52531 and PCT/US2010/038896 disclose the methods that are applicable only to the synthesis of aggregate particles of limited compositions and structures.

For example, PCT/US09/52531 discloses only a method wherein the aggregates of ZnO nanoparticles are synthesized by a solvothermal method as colloidal solutions directly from a Zn containing precursor in a solvent wherein the ZnO nanoparticles spontaneously assemble into aggregates during a carefully controlled reaction. The method of forming aggregate particles for DSC photoelectrodes disclosed in PCT/US09/52531 is applicable only to the synthesis of aggregates of ZnO nanoparticles and therefore is not readily extended to the production of aggregate particles from the nanomaterials of other types of structures and/or compositions such as TiO₂ nanoparticles and nanotubes.

PCT/US2010/038896 discloses a hydrothermal method and a solvothermal method wherein the aggregates of TiO₂ nanoparticles are synthesized directly from a Ti containing precursor solution wherein the TiO₂ nanoparticles spontaneously assemble into aggregates during a carefully controlled reaction, optionally utilizing water-in-oil emulsions. These methods are applicable only to the synthesis of aggregate particles of TiO₂ nanoparticles.

As an example of TiO₂ aggregate particles comprising nanomaterials other than nanoparticles, PCT/US2010/038896 also discloses a precipitation method wherein the aggregate particles of TiO₂ nanotubes are formed by washing the TiO₂ nanotube intermediates comprising Na first with ethanol and then with a HCl solution. This method is only applicable to the synthesis of aggregate particles of TiO₂ nanotubes.

PCT/US2010/038896 also discloses the aggregate particles of TiO₂ nanoparticles in the form of mesoporous particles which are synthesized by converting non-porous particles into mesoporous structures. The synthesis of aggregate particles in the form of mesoporous particles disclosed in PCT/US2010/038896 is applicable only to the aggregate particles of TiO₂ nanoparticles.

Thus, there remains a need for a method to synthesize the aggregate particles of nanomaterials designed to maximize the beneficial effects imparted by nanomaterials in DSC applications.

### SUMMARY OF THE INVENTION

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In certain embodiments, a method of forming aggregate particles of nanomaterials is provided. In certain embodiments, the method of forming aggregate particles of nanomaterials comprises (a) preparing a dispersion of nanomaterials in a solvent; (b) forming aerosol droplets of the dispersion; and (c) removing the solvent to form aggregate particles. In certain embodiments, the solvent comprises a polymeric additive. In certain embodiments, the polymeric additive is removed from the aggregate particles by annealing the aggregate particles.

In certain embodiments, forming aerosol droplets comprises an electrostatic force. In certain embodiments, forming aerosol droplets comprises a pneumatic force. In certain embodiments, forming aerosol droplets comprises a sonication. In certain embodiments, forming aerosol droplets comprises an electrostatic force and a pneumatic force. In certain embodiments, forming aerosol droplets comprises an electrostatic force and a sonication. In certain embodiments, forming aerosol droplets comprises a pneumatic force and a sonication.

In certain embodiments, forming aerosol droplets comprises an electrostatic force, a pneumatic force, and a sonication.

In certain embodiments, a nanomaterial is selected from the group consisting of titanium dioxide, zinc oxide, and mixtures thereof. In certain embodiments, a nanomaterial is selected from the group consisting of a nanotube, a nanoparticle, a nanowire, and mixtures thereof. In certain embodiments, nanotubes range in size from about 1 nm to about 100 μm. In certain embodiments, nanotubes have a length from about 1 nm to 100 μm. In certain embodiments, nanotubes have a diameter from about 1 nm to 10 μm. In certain embodiments, nanoparticles have a diameter from about 1 nm to 10 μm. In certain embodiments, nanowires have a length from about 1 nm to 100 μm. In certain embodiments, nanowires have a diameter from about 1 nm to 10 μm.

In certain embodiments, nanomaterials comprise substantially crystalline structures. In certain embodiments, the crystalline structures comprise the anatase phase of TiO₂. In certain embodiments, the crystalline structures comprise the rutile phase of TiO₂. In certain embodiments, the crystalline structures comprise a mixture of the anatase phase of TiO₂ and the rutile phase of TiO₂.

In certain embodiments, aggregate particles have a diameter of from about 1 nm to about 100 μm. In certain embodiments, aggregate particles have a surface area from about 1 cm²/g to about 1,000 m²/g. In certain embodiments, aggregate particles further comprise interconnecting pores having a diameter from about 0.1 nm to 10 μm. In certain embodiments, aggregate particles are in the form of hollow particles.

In certain embodiments, a solvent is a mixture of ethanol and water. In certain embodiments, a solvent further comprises a nanomaterial precursor.

In certain embodiments, the concentration of nanomaterials in the dispersion is from about 1 to 30% by weight. In certain embodiments, the concentration of polymeric additive in the solvent is from about 1 to 30% by weight. In certain embodiments, the polymeric additive is polyvinylpyrrolidone. In certain embodiments, the polymeric additive comprises polyvinylpyrrolidone and a polystyrene latex sphere.

In certain embodiments, a method of forming a photoelectrode of a solar cell is provided. In certain embodiments, a method of forming a photoelectrode of a solar cell comprises (a) preparing a dispersion of nanomaterials in a solvent; (b) forming aerosol droplets of the dispersion; (c) removing the solvent to form aggregate particles; and (d) depositing the aggregate particles on a substrate as a layer.

In certain embodiments, the solvent comprises a polymeric additive. In certain embodiments, the polymeric additive is removed from the aggregate particles by annealing the aggregate particles. In certain embodiments, the polymeric additive is removed from the aggregate particles by annealing the aggregate particles after the aggregate particles are deposited on the substrate. In certain embodiments, the aggregate particles comprise a plurality of aggregate particles of a nanomaterial. In certain embodiments, the nanomaterial is selected from the group consisting of titanium dioxide, zinc oxide, and mixtures thereof. In certain embodiments, the nanomaterial is selected from the group consisting of a nanotube, a nanoparticle, a nanowire, and mixtures thereof.

In certain embodiments, a method of forming a photoelectrode of a solar cell further comprises depositing a nanomaterial. In certain embodiments, the nanomaterial is deposited on the substrate before the aggregate particles are deposited. In certain embodiments, the nanomaterial is deposited after the aggregate particles are deposited on the substrate. In certain embodiments, the aggregate particles are combined with the nanomaterials and deposited together on the substrate. In certain embodiments, the nanomaterial is selected from the group consisting of a nanotube, a nanoparticle, a nanowire, and mixtures thereof.

In certain embodiments, a method of forming a photoelectrode of a solar cell further comprises heat treating the substrate.

In certain embodiments, the surface area of the photoelectrode is from about 1 cm²/g to 1,000 cm²/g. In certain embodiments, the thickness of the photoelectrode is from about 1 nm to about 1 mm.

In certain embodiments, a layer of aggregate particles provides enhanced light scattering within the layer compared to a photoelectrode comprising a layer of nanomaterials in non-aggregated particle form.

These and other features of the present teachings are set forth herein.

### DESCRIPTION OF THE DRAWINGS

The foregoing aspects and many of the attendant advantages of this invention will become more readily appreciated as the same become better understood by reference to the following detailed description, when taken in conjunction with the accompanying drawings.

FIG. 1 shows an experimental set-up of an electrospray apparatus useful for performing methods provided herein.

FIG. 2A to 2C show scanning electron microscope (SEM) images of films annealed at 450° C. comprising: FIG. 2A, P25 (Evonik Degussa) TiO₂ nanocrystallites; FIG. 2B, aggregate particles of P25 TiO₂ nanocrystallites produced by an electrospray method; and FIG. 2C, a single aggregate particle at a higher magnification with a bar scale of 100 nm.

FIG. 3 shows the X-ray diffraction (XRD) patterns of TiO₂ films on fluorine-doped tin oxide (FTO) substrates annealed at 450° C. An XRD pattern of P25 TiO₂ nanocrystallites and that of aggregate particles produced by an electrospray method comprising P25 TiO₂ nanocrystallites are shown.

FIGS. 4A and 4B show SEM images of porous TiO₂ aggregate particles prepared with a mixture of P25 TiO₂ nanocrystallites and polystyrene nanoparticles by an electrospray method; FIG. 4A is a low magnification image; and FIG. 4B is a high magnification image.

FIGS. 5A to 5D show SEM images of: FIGS. 5A and 5B are film of TiO₂ nanocrystallites (sample number=N₁A₀); FIGS. 5C and 5D are films of TiO₂ aggregate particles produced by an electrospray method (sample number=N₀A₁). All films were annealed at 450° C.

FIGS. 6A to 6D show SEM images of films after annealing at 450° C. comprising the mixtures of TiO₂ nanoparticles and aggregate particles of TiO₂ nanoparticles produced by an electrospray method: FIG. 6A is N_{0.8}A_{0.2}; FIG. 6B is N_{0.7}A_{0.3}; FIG. 6C is N_{0.6}A_{0.4}; and FIG. 6D is N_{0.5}A_{0.5}. Sample number N_{X}A_{Y} denotes a mixture of TiO₂ nanoparticles and aggregate particles of TiO₂ nanoparticles at a mixing ratio of X to Y by weight. The scale bars in FIGS. 6A to 6D are 1 μm.

FIGS. 7A and 7B show SEM images of hollow aggregate particles of TiO₂ nanoparticles produced by an electrospray method: FIG. 7A is under low magnification; and FIG. 7B is under high magnification.

FIGS. 8A to 8D show SEM images of aggregate particles of TiO₂ nanoparticles with different polymer additives produced by an electro spray method: FIG. 8A, polyethylene glycol (PEG) having molecular weight (M_{w})≈2×10⁴; FIG. 8B, PEG (M_{w}≈400); FIG. 8C, polyvinylpyrrolidone (PVP) with M_{w}≈1.3×10⁶; and FIG. 8D, PVP (M_{w}≈5.5×10⁴).

FIGS. 9A to 9C show SEM images of aggregate particles of TiO₂ nanoparticles prepared by an electrospray method under different voltages: FIG. 9A is taken at 6 kV; FIG. 9B is taken at 10 kV; and FIG. 9C is taken at 14 kV.

FIGS. 10A to 10C show SEM images of aggregate particles of TiO₂ nanoparticles prepared by an electrospray method with different ejection speeds: FIG. 10A is at 0.1 ml/h; FIG. 10B is at 0.2 ml/h; and FIG. 10C is at 0.3 ml/h.

FIGS. 11A to 11C show SEM images of the aggregate particles of ZnO nanowires prepared by an electrospray method.

FIG. 12 shows the current-voltage (I-V) curve of a DSC with the photoelectrode comprising the aggregate particles of TiO₂ nanoparticles prepared by an electrospray method and the I-V curve of a DSC with the photoelectrode comprising P25 TiO₂ nanoparticles.

FIG. 13 shows the I-V curves of DSCs with the photoelectrodes comprising N₁A₀, N_{0.8}A_{0.2}, N_{0.7}A_{0.3}, N_{0.6}A_{0.4}, N_{0.5}A_{0.5}, and N₀A₁ samples of FIGS. 5A to 5D and FIGS. 6A to 6D.

### DETAILED DESCRIPTION OF THE INVENTION

The provided embodiments include aggregate nanomaterials, methods for forming aggregate nanomaterials, layers formed from the aggregate nanomaterials, and devices incorporating the aggregate nanomaterials.

While illustrative embodiments have been illustrated and described, it will be appreciated that various changes can be made therein without departing from the spirit and scope of the invention.

Unless otherwise defined, all technical and scientific terms used herein have the same meaning as commonly understood by one of ordinary skill in the art. Although methods and materials similar or equivalent to those described herein can be used in the practice or testing of the claims, suitable methods and materials are described below. Publications, patent applications, patents, and other references mentioned herein are incorporated by reference in their entirety. In the case of conflict, the present specification, including definitions, will control. In addition, the materials, methods, and examples are illustrative only and not intended to be limiting.

Unless specific definitions are provided, the nomenclatures utilized in connection with, and the laboratory procedures and techniques of, analytical chemistry, synthetic organic and inorganic chemistry, and chemical processing described herein are those well known and commonly used in the art. Standard techniques may be used for chemical syntheses, chemical analysis, and material processing and handling.

In this application, the use of the singular includes the plural unless specifically stated otherwise. In this application, the use of “or” means “and/or” unless stated otherwise. In the context of a multiple dependent claim, the use of “or” refers back to more than one preceding independent or dependent claim in the alternative only. The use of the term ‘including”, as well as other forms, such as “includes” and “included”, is not limiting. Also, terms such as “element” or “component” encompass both elements and components comprising one unit and elements and components that comprise more than one subunit unless specifically stated otherwise.

The term “nanomaterials” refers to materials on the order of 1 Angstrom to 100 μm in the smallest measured dimension (e.g., diameter of a nanosphere). In certain embodiments, the size range of nanomaterials is anything less than 100 nm. In certain embodiments, the size range of nanomaterials is 1 nm-1 μm. In certain embodiments, the size range of nanomaterials is 10-100 nm.

Nanomaterials described herein are suitable for use in forming aggregates of the nanomaterials and/or for use in non-aggregate form to enhance the properties of aggregated nanomaterials (i.e., films of combined aggregate nanomaterials and non-aggregated nanomaterials can have superior properties to neat films of either the aggregate or non-aggregated nanomaterials). Embodiments of the invention include aggregates of first nanomaterials and combined films of aggregates of first nanomaterials and non-aggregated second nanomaterials, wherein the first nanomaterials and the second nanomaterials are the same or different.

Examples of the composition of nanomaterials include, but are not limited to, metal oxides and semiconductor materials such as TiO₂, ZnO, SnO₂, Fe₂O₃, In₂O₃, Al₂O₃, SiO₂, WO₃, Sb₂O₃, ZrO₂, PbO, CdSe, CdS, CdTe, ZnSe, ZnS, ZnTe, PbS, PbSe, PbTe, GaAs, GaP, GaN, InP, and InAs, and combinations or composites thereof.

In certain embodiments, nanomaterials are TiO₂ nanomaterials. In certain embodiments, the TiO₂ nanomaterials are TiO₂ nanoparticles (also referred to herein as “nanocrystallites”) or nanotubes.

TiO₂ nanomaterials may be synthesized by methods well known in the art. For example and not limitation, TiO₂ nanomaterials may be synthesized by sol-gel methods, hydrothermal methods, or flame pyrolysis of TiO₂ precursors such as, for example and not limitation, titanium tetraisopropoxide, or titanium tetrachloride. In certain embodiments, commercially available TiO₂ nanomaterials may be used.

In certain embodiments, nanomaterials are ZnO nanomaterials. In certain embodiments, the ZnO nanomaterials are ZnO nanoparticles or nanowires. ZnO nanomaterials may be synthesized by methods well-known in the art. For example and not limitation, ZnO nanomaterials may be synthesized by solvothermal methods utilizing ZnO precursors such as, for example and not limitation, zinc acetate refluxed in diethylene glycol at a temperature of 190° C., or a solution reaction between zinc acetate and potassium hydroxide.

The term “hydrothermal method” refers to a thermally induced reaction carried out in an aqueous solution. In certain embodiments, the reaction may be carried out at ambient pressure (e.g., under a refluxing condition). In certain embodiments, the reaction may be carried out at elevated pressure (e.g., in an autoclave).

The term “solvothermal method” refers to a thermally induced reaction carried out in solutions substantially free of water.

In certain embodiments, nanomaterials comprise substantially crystalline structures. In certain embodiments, nanomaterials comprise the anatase phase of TiO₂. In certain embodiments, nanomaterials comprise the rutile phase of TiO₂. In certain embodiments, nanomaterials comprise both the anatase and rutile phases of TiO₂.

As described in more detail below in Example 1, X-ray diffraction (XRD) patterns of TiO₂ films reveal that both aggregated and non-aggregated nanoparticle films possess nearly identical patterns, indicating the presence of highly crystallized anatase and rutile phases. Thus indicating that the aerosolization (e.g., by electrospray) and subsequent drying and annealing process did not cause any detectable change in the crystallinity and crystalline phases of the constituent TiO₂ nanoparticles, although there is a noticeable difference between the morphology of the films. Therefore, embodiments of the methods provided herein result in nanomaterial aggregates having similar crystallinity to non-aggregate nanomaterials, but different morphology. The morphology of the nanomaterial aggregates results in improved pore volume and surface area compared to non-aggregate nanomaterials, which results in improved characteristics of DSCs incorporating the aggregate nanomaterials.

The term “aggregate particles” refers to particles on the order of 1 nm to 100 μm which are produced by agglomerating nanomaterials. In certain embodiments, the size (e.g., diameter) of aggregate particles is 1 nm to 100 μm. In certain embodiments, the size of aggregate particles is 10 nm to 10 μm. In certain embodiments, the size of aggregate particles is 100 nm to 1 μm.

In certain embodiments, the surface area per unit mass of aggregate particles is comparable to that of the non-aggregated nanomaterials.

In certain embodiments, aggregate particles are in the form of hollow particles.

The term “nanomaterial precursors” refers to the compositions comprising the monomeric compounds which polymerize into nanomaterials.

The term “TiO₂ precursors” refers to the compositions comprising the monomeric compounds which polymerize into TiO₂ nanomaterials. Examples of TiO₂ precursors include, but are not limited to, titanium tetraisopropoxide, titanium tetrabutoxide, titanium tetraethoxide, titanium tetraoxychloride, titanium tetrachloride and titanium n-propoxide.

The term “ZnO precursors” refers to the compositions comprising the monomeric compounds which polymerize into ZnO nanomaterials. Examples of ZnO precursors include, but are not limited to, zinc acetate, zinc chloride, zinc nitrate, and zinc sulfate.

In certain embodiments, aggregate particles may comprise TiO₂ or ZnO precursors and/or nanomaterials in a residual amount. In certain embodiments, aggregate particles are deliberately combined with TiO₂ or ZnO precursors and/or nanomaterials. In certain embodiments, aggregate particles have a plurality of sizes.

The term “electrostatic force” refers to a mechanism of breaking down the dispersions of nanomaterials into aerosol droplets by applying an intensive electric field to the dispersion of nanomaterials discharged from a capillary nozzle.

The term “electrospray method” refers to a method of forming aerosol droplets of the dispersion of nanomaterials by utilizing an electrostatic force.

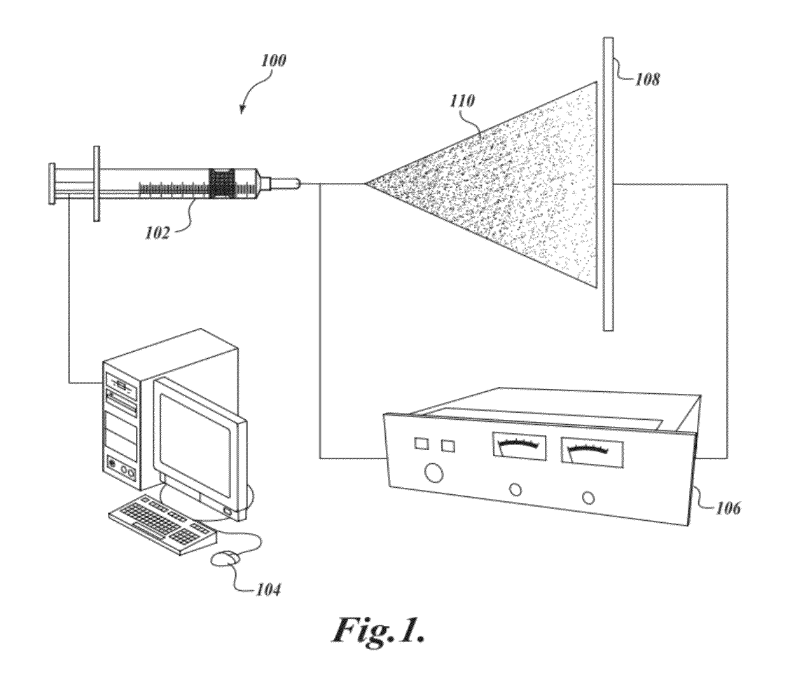

An exemplary system 100 for performing electro spray, as used in representative methods provided herein, is illustrated in FIG. 1, Referring to FIG. 1, a syringe 102 containing a solution is operatively connected to a computer 104, which controls the flow rate of solution out of the syringe 102 (e.g., through mechanical means). A high-voltage power supply 106 is in electronic communication with the syringe 102, such that an electrostatic force can be applied to the syringe 102 and solution delivered therefrom. The high-voltage power supply 106 is also in electronic communication with a substrate 108.

In operation, the system 100 of FIG. 1 produces an electrospray 110 comprising an aerosol of the solution held by the syringe 102. Specifically, the computer 104 controls the delivery of solution from the syringe 102 while the high-voltage power supply 106 applies a voltage across the syringe 102 and the substrate 108 such that an electrostatic force at the tip of the syringe 102 produces an aerosol of the solution in an electrospray 110 traveling from the syringe 102 to the substrate 108. The electrospray 110 impinges upon the substrate 108. As will be described in more detail below, embodiments provided herein utilize electrospray to form aggregate particles of nanomaterials.

The term “sonication” refers to a mechanism of breaking down the dispersion of nanomaterials into aerosol droplets by applying sound energy to the dispersion of nanomaterials by utilizing an ultrasonic spray nozzle.

The term “pneumatic force” refers to a mechanism of breaking down the dispersion of nanomaterials into aerosol droplets by combining the dispersion of nanomaterials with a gas by utilizing a pneumatic spray nozzle.

The term “dye-sensitized solar cell” (DSC) refers to a photovoltaic device based on a photoelectrochemical system comprising an anode and a cathode to define a cell which is filled with an electrolyte wherein the anode consists of a semiconducting layer coated with a photosensitizer which absorbs the light and emits an electron.

The term “photoelectrode” refers to a semiconducting layer in the anode of a DSC. A photoelectrode is a porous film comprising, but not limited to, TiO₂ or ZnO aggregate particles and, optionally, TiO₂ or ZnO nanomaterials such as TiO₂ or ZnO nanoparticles substantially free of agglomeration. The photoelectrode film features a very large surface area and includes submicron-sized TiO₂ or ZnO aggregate particles. In certain embodiments, the photoelectrode film consists of submicron-sized TiO₂ or ZnO aggregate particles.

The term “aerosol droplets” refers to liquid droplets, comprising a dispersion of solid particles, in a gas (e.g., a spray of liquid containing dispersed solid particles).

The term “removing the solvent to form aggregate particles” refers to a process wherein the agglomeration of particles is confined inside the aerosol droplets and the aggregate particles are substantially free of agglomerating with each other.

The term “annealing” refers to a process of subjecting a material to a thermal treatment.

As used herein, the terms “dispersion” and “suspension” refer to mixtures of solid particles (e.g., nanomaterials) in a liquid, wherein the solid particles are not solvated by the liquid.

The present invention is directed to aggregate particles of inorganic nanomaterials, their methods of production, and the devices and compositions that incorporate those aggregate particles. In certain embodiments, the compositions and structures of said aggregate particles are precisely size and/or shape controlled to optimize end-use performance. More specifically, the present invention is directed to the aggregate particles of nanomaterials which improve the solar-to-electric PCE of DSCs by the enhanced light scattering.

In certain embodiments, a method of synthesizing the aggregate particles of nanomaterials is provided. In certain embodiments, the method of synthesizing the aggregate particles of nanomaterials for a DSC comprises the steps of:
(a) forming aerosol droplets of a dispersion comprising a first nanomaterial in a liquid; and
(b) removing the liquid from the droplets to form aggregate particles of the first nanomaterial.

Preparing a dispersion of nanomaterials, in certain embodiments, includes mixing nanomaterials with a liquid. In alternative embodiments, the nanomaterials are synthesized in the liquid to form the dispersion.

Representative liquids include, but are not limited to, water, ethanol, propanol, butanol, and mixtures thereof. The appropriate liquid for use in the methods can be determined by one of skill in the art, and depends on the nanomaterials used, any liquid-based reactions that must be facilitated, and any optional additives to the liquid.

Representative nanomaterials for preparing the dispersion have been discussed above (e.g., metal oxide nanoparticles). Nanomaterials may be functionalized, or otherwise treated, to facilitate forming a dispersion in the liquid.

As will be discussed in further detail below, forming aerosol droplets of the dispersion, in certain embodiments, includes techniques using electrostatic force (e.g., electrospray), pneumatic force, sonication, and combinations thereof.

As will be discussed in further detail below, removing the liquid to form aggregate particles of the nanomaterials, in certain embodiments, includes heating the aerosol droplets (e.g., aerosol droplets deposited on a substrate) to a temperature sufficient to remove the liquid. In embodiments where the liquid contains a polymer additive, heating to remove the liquid will also remove the polymer additive if sufficient heat is applied to remove both the liquid and polymer additive. Alternatively, heating may only remove the liquid and the polymer additive may remain in the aggregate. When only the polymer additive remains in the aggregate, further heating may be applied to remove the polymer additive to provide the aggregate free of polymer additive and the liquid.

In certain embodiments, the solvent comprises a polymeric additive. Polymeric additives can be useful in several ways when forming aggregates. First, polymeric additives can be used to facilitate dispersion of the nanomaterials in liquid, as set forth below in Examples 1, 2, 4, 5, 8, and 9.

Second, polymeric additives, such as polymer spheres, can be used to control the pore size and volume of the aggregated materials. As set forth in Example 2, polymer particles can be used to enlarge the pore size of TiO2 nanoparticle aggregates when compared to aggregates formed without the polymer particles. Enlarged pore size can increase pore volume and aggregate surface area, which in turn can increase device performance related to the aggregate surface, such as the conversion efficiency of DSCs formed with the aggregates.

Examples of polymeric additives include, but are not limited to, polyvinylpyrrolidone (PVP), polyethylene glycol (PEG), polystyrene latex spheres, and mixtures thereof. Polymeric additives may be soluble in the solvent or dispersible in the solvent. Additionally, while not a polymer, ethyl acetate can be used as an additive in the same manner as the polymeric additives listed above. Therefore, the use of the term “polymeric additive” herein defines a group that includes polymers and ethyl acetate.

In certain embodiments, the polymeric additive is removed from the aggregate particles by annealing the aggregate particles. In certain embodiments, aggregate particles comprise a polymeric additive. In certain embodiments, aggregate particles are substantially free of polymeric additive.

While not wishing to be bound by theory, the inventors believe that the improvement in the solar-to-electric PCE of DSC comprising the controlled aggregate particles provided herein as the photoelectrode materials results from the enhanced light scattering caused by the aggregates whose size is comparable to the wavelength of light. Photoelectrodes of size-controlled aggregates capture incident light more efficiently than photoelectrodes comprising nanomaterials free of agglomeration, while maintaining a very high surface area to volume ratio of photoelectrodes, which results in high dye loading. In addition, improved light capturing by the photoelectrodes enables the reduction in the thickness of the photoelectrodes, thereby reducing the recombination of photogenerated electrons.

The aggregate nanomaterials provided herein can be used to form a light scattering layer in the photoelectrode film of DSCs (e.g., in addition to, or instead of, forming the photoelectrode). The advantage of a light scattering layer comprising aggregate particles is that the resulting photoelectrode film possesses a large internal surface area while providing the function of effective light scattering, leading to enhanced light absorption by DSCs. As set forth in Example 8, the TiO₂ and ZnO aggregate particles in Examples 1, 2, 4, 5 and 6, are all exemplary aggregate nanomaterials that are useful as a light scattering layer in DSCs.

In certain embodiments, the formation of aerosol droplets of the dispersion of nanomaterials is effected by an electrostatic force (e.g., electrospray deposition as discussed above with regard to FIG. 1). In certain such embodiments, liquid droplets are generated based on a mechanism of electrostatic charging while an intensive electric field (˜1 kV/cm) is applied to the liquid discharged from a capillary nozzle. As the liquid is forced to hold increasing amount of charges, it becomes unstable and eventually sprays away from the nozzle in a cloud of highly charged droplets. These droplets fly to a potential surface opposite in charge to their own, and meanwhile, shrink and form into solid spheres as the solvent evaporates.

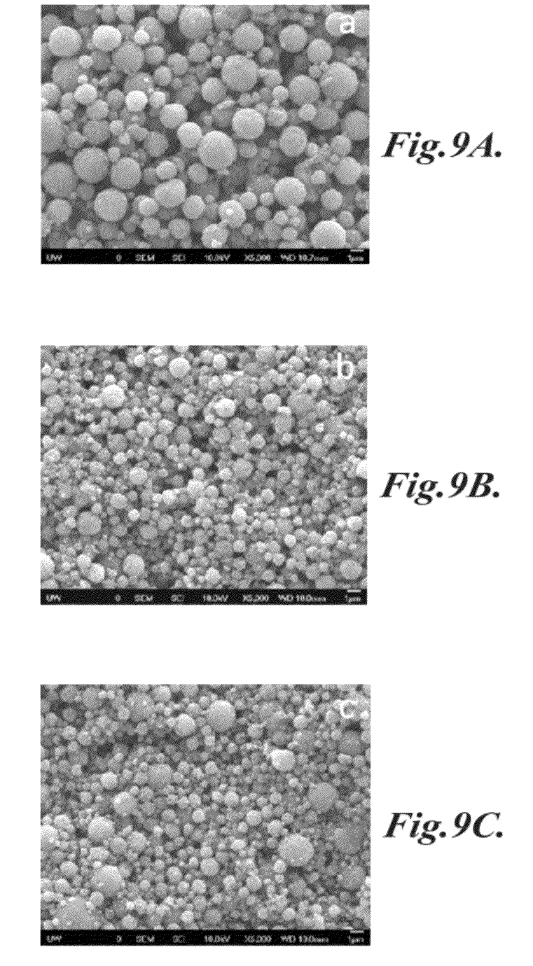

As described in Example 5, and illustrated in FIGS. 9A to 9C, the size of the electric field applied during electrospray has an impact on the size and morphology of the formed aggregates. In one embodiment of the invention, the electric field applied during electrostatic formation of aggregates is from 0.1 kv/cm to 10 kV/cm.

In exemplary embodiments, the dispersion of nanomaterials is prepared with a mixture of water and ethanol containing 5 wt % TiO₂ nanoparticles and 1 wt % additive of polymer such as PVP. The solution is put in a syringe with an ejection speed of approximately 5 ml/h. A voltage of about 25 kV is applied between the nozzle connected with the syringe and a conductive substrate placed at approximately 20 cm away from the nozzle. Aggregates of the nanomaterials are formed on the substrate as the dispersion of nanomaterials is discharged from the nozzle. The resulting aggregates are a powder that is collected and then annealed at approximately 450° C. to remove the polymer and recover the aggregate particles of TiO₂ nanoparticles.

The size of the aggregate particles can be controlled by changing the concentration of TiO₂ nanoparticles and the applied voltage. In representative embodiments, the size of the aggregates is from 50 nm to 15 microns when formed using nanoparticle dispersions of a concentration from 0.01 g/mL to 1 g/mL and an electrospray voltage of from 0.1 kV/cm to 10 kV/cm.

The porosity of the aggregates is dependent on the concentration of polymer (in representative embodiments: 0.001 g/mL to 1 g/mL) and the annealing temperature (in representative embodiments: 200° C. to 700° C.

Annealing the aggregates has at least two purposes: 1) to remove polymer from aggregates (if a polymer additive is used during aggregate formation); and 2) to bind nanoparticles and aggregates to each other and to the substrate.

In certain embodiments, a combination of annealing with other methods (e.g., washing the aggregates with solvent or, exposing the aggregates to microwave) can be used to remove polymer.

In certain embodiments, residual polymer remains in the aggregates and is not removed (i.e., only the solvent from aggregate formation is removed while the polymer additive is integrated into the aggregates)

Example 1, set forth below, describes the fabrication of TiO₂ nanoparticle aggregates. Additionally, the benefits of aggregate nanoparticles formed using the methods provided herein compared to non-aggregated nanoparticles is described in Example 1. Notably, aggregates of commercially available (spherical) P25 TiO₂ nanoparticles were found to have 1.7 times the pore volume of non-aggregated P25 nanoparticle films.

In certain embodiments, the formation of aerosol droplets of the dispersion of nanomaterials is effected by a sonication utilizing an ultrasonic spray nozzle. In this method, a liquid feed solution is pulverized into small droplets from the tip of spray nozzle vibrating at the ultrasonic frequency. An example of ultrasonic spray pyrolysis apparatus is disclosed by the Korean patent KR100925150 by Kim, Cho, and Hwang.

The dispersions of nanomaterials prepared for the production of aggregate particles by the electro spray method can also be utilized to produce the aggregate particles of nanomaterials by sonication.

In certain embodiments, the formation of aerosol droplets of the dispersion of nanomaterials is effected by a pneumatic force utilizing a pneumatic spray nozzle wherein a liquid feed solution is mixed with a compressed gas internally or externally of the spray nozzle. In the production of granules comprising nanomaterials, pneumatic spray nozzles are disclosed by, for example, Faure et. al. in a paper titled “Spray Drying of TiO₂ Nanoparticles into Redispersible Granules” (Powder Technology, in press) and by Lindeløv and Wahlberg in a paper titled “Spray Drying for Processing of Nanomaterials” (Journal of Physics: Conference Series 170 (2009), and by Y. C. Kang, S. B. Park, and Y. W. Kang in Nanostructured Materials 5, 777 (September-December, 1995). The dispersions of nanomaterials prepared for the production of aggregate particles by the electrospray method can also be utilized to produce the aggregate particles of nanomaterials by a pneumatic force.

Pyrolysis fabrication is a method based on the generation of aerosol droplets via sonication or pneumatic force followed by a rapid evaporation of the solvent at elevated temperatures (−500-800° C.) to form an aggregate structure comprising nanomaterials. The precursor solutions for the electrospray methods mentioned in Examples 1, 2, 5, and 6 can also be utilized in the production of TiO₂ or ZnO aggregate particles by pyrolysis with sonication or pneumatic force, as set forth in Example 7.

Additionally, aerosol droplets of the dispersions of nanomaterials can be formed using any combination of electrostatic, pneumatic, and sonication forces.

In certain embodiments, the aerosol droplets are subjected to an elevated temperature (e.g., ˜500-800° C.) in ambient pressure or reduced pressure (i.e., vacuum) to evaporate the solvent as well as to remove the polymeric additive.

In certain embodiments, the aggregate particles of nanomaterials are characterized by sizes on the order of 1 nm to 100 μm and those aggregate particles comprise nanomaterials on the order of 1 Angstrom to 100 μm. In certain embodiments, the aggregate particles of nanomaterials are characterized by sizes on the order of 10 nm to 100 μm and those aggregate particles consist of nanomaterials on the order of 1 nm to 1 μm. In certain embodiments, the aggregate particles of nanomaterials are characterized by sizes on the order of 100 nm to 1 μm and those aggregate particles consist of nanomaterials on the order of 10 nm to 100 nm.

In certain embodiments, the aggregate particles of nanomaterials are powdery free-flowing materials. In certain such embodiments, the aggregate particles of nanomaterials are dispersible, detached from each other, and the aggregate particles of nanomaterials do not agglomerate under ambient conditions. Therefore, in representative embodiments, aggregate particles remain as free flowing powders under normal storage/shipping conditions (i.e., room temperature in the air) and do not require special handling.

In certain embodiments, the constituent nanomaterials that comprise aggregate particles may take the form of, but are not limited to the forms of, nanoparticles, nanotubes, nanorods, nanowires, nanobelts, and nanoflowers.

In certain embodiments, compositions of aggregate particles of nanomaterials for a solar cell are provided. In certain embodiments, a solar cell is a DSC.

In certain embodiments, the TiO₂ precursor is titanium tetraisopropoxide.

In certain embodiments, the ZnO precursor is zinc acetate.

In certain embodiments, aggregate particles are porous particles comprising: an aggregate diameter of 1 nm to 100 μm; a pore diameter of 1 nm to 10 μm; and a surface area of 1 cm²/g to 1,000 m²/g. In certain embodiments, aggregate particles are porous particles comprising: an aggregate diameter of 100 nm to 100 μm; a pore diameter of 0.1 nm to 1 μm; and a surface area of 50 cm²/g to 1,000 m²/g.

In certain embodiments, aggregate particles comprise TiO₂ nanotubes. In certain embodiments, TiO₂ nanotubes comprise a tube diameter of 0.1 nm to 10 μm and a tube length of 0.1 nm to 100 μm. In certain embodiments, TiO₂ nanotubes comprise a tube diameter of 1 nm to 1 μm and a tube length of 1 nm to 10 μm.

In certain embodiments, aggregate particles comprise TiO₂ nanoparticles. In certain embodiments, the range of diameter of TiO₂ nanoparticles is 0.1 nm to 1 μm. In certain embodiments, the range of diameter of TiO₂ nanoparticles is 1 nm to 100 nm. In certain embodiments, the range of diameter of TiO₂ nanoparticles is 5 nm to 50 nm.

In certain embodiments, aggregate particles comprise ZnO nanowires. In certain embodiments, ZnO nanowires comprise a wire diameter of 0.1 nm to 10 μm and a wire length of 0.1 nm to 100 μm. In certain embodiments, ZnO nanowires comprise a wire diameter of 1 nm to 1 μm and a wire length of 1 nm to 10 μm.

In certain embodiments, nanomaterials are in the form of sol or dry particles of nanoparticles. In certain embodiments, nanomaterials are in the form of aqueous sol of colloidal nanoparticles. In certain embodiments, nanomaterials are in the form of dry nanotubes. In certain embodiments, nanomaterials are in the form of dry nanowires.

In certain embodiments, TiO₂ nanoparticles are synthesized by the hydrolysis of TiO₂ precursors by a hydrothermal method. Examples of hydrothermal methods include, but are not limited to, methods comprising the steps of: formation of TiO₂ sol by combining titanium tetraisopropoxide, deionized (DI) water, and acetate acid; and hydrothermal growth of the resulting TiO₂ sol in an autoclave at elevated temperature.

In certain embodiments, nanomaterials are synthesized by a sol-gel method from precursors. Examples of sol-gel methods include the hydrolysis of TiO₂ precursor such as titanium tetraisopropoxide at ambient temperature and pressure.

In certain embodiments, nanomaterials are synthesized by a solvothermal method from precursors. Examples of solvothermal methods include, but are not limited to, the hydrolysis of ZnO precursors, such as zinc acetate, at elevated temperature in diethylene glycol.

In certain embodiments, the formation of aggregate particles is effected from an emulsion comprising nanomaterials. In certain embodiments, the formation of aggregate particles is effected from an oil-in-water emulsion wherein the nanomaterials comprise the water phase. In certain embodiments, the formation of aggregate particles is effected from a water-in-oil emulsion wherein the nanomaterials comprise the oil phase.

In certain embodiments, commercially available nanomaterials can be utilized because the provided process to effect the formation of aggregate particles is applicable to the formation of aggregate particles from pre-synthesized nanomaterials of variable compositions and structures. Exemplary commercially available nanomaterials include, but are not limited to, P25 TiO₂ nanospheres (Evonik Degussa), TiO₂ or ZnO nanoparticles (Nanostructured & Amorphous Materials, Inc.), nanoActive TiO₂ or ZnO powder (NanoScale Corporation), Titanium Dioxide Nanopowder (Alpha Nanomaterials, LLC), and TiO₂ nanopowder (M.K. IMPEX CANADA).

The aggregate particles provided herein may be used alone or in combination with conventional nanoparticles known to those of skill in the art as utilized in the manufacturing DSCs. In certain embodiments, this invention relates to a method of forming a photoelectrode of a solar cell comprising aggregate particles of nanomaterials such as, for example but without limitation, TiO₂ or ZnO nanomaterials comprising depositing aggregate particles formed according to a method provided herein on a substrate to provide an aggregate layer.

Examples 8 and 9 describe the fabrication of DSCs using the aggregates provided herein as the photoelectrode. Notably, in Example 9, the use of aggregates of P25 nanoparticles improves the solar-to-electric conversion efficiency from 4.8% to 5.9%. Additionally in Example 9, combined films of aggregate nanoparticles mixed with non-aggregated nanoparticles show improved conversion efficiency compared to neat films of the aggregates and neat films of the non-aggregated nanoparticles. Therefore, the aggregated nanomaterials provided herein provide improved solar cells when compared to solar cells incorporating non-aggregated nanomaterials.

In certain embodiments, the polymeric additive is removed from the aggregate particles by annealing the aggregate particles prior to depositing the aggregate particles on the substrate.

In certain embodiments, the polymeric additive is removed from the aggregate particles by annealing the aggregate particles after the aggregate particles are deposited on the substrate, forming a film of aggregate particles that is substantially free of polymeric additive and is securely bound to the substrate.

In certain embodiments, a photoelectrode of a solar cell is formed from a mixture of TiO₂ or ZnO nanoparticles and TiO₂ or ZnO aggregate particles. In certain embodiments, a photoelectrode of a solar cell is formed by depositing TiO₂ or ZnO nanoparticles first and then depositing TiO₂ or ZnO aggregate particles in that order.

In certain embodiments, this invention relates to the functional materials and devices which comprise the aggregate particles of nanomaterials wherein the performance of functional materials and devices comprising said aggregate particles are superior to that of functional materials and devices comprising the nanomaterials free of agglomerations.

In certain embodiments, this invention relates to a photoelectrode of solar cell. In certain embodiments, said photoelectrode comprises the aggregate particles of this invention and the nanomaterials substantially free of agglomeration.

In certain embodiments, this invention relates to the photoelectrode of DSC. In certain embodiments, the thickness of the photoelectrode of DSC is 1 nm to 1 mm. In certain embodiments, the thickness of the photoelectrode of DSC is 10 nm to 100 μm. In certain embodiments, the thickness of the photoelectrode of DSC is 1 μm to 50 μm.

In exemplary embodiments, photoelectrode films of aggregate particles have gaps between aggregate particles when deposited. Filling these gaps with non-aggregated nanoparticles will increase the surface area per unit volume of the photoelectrode, leading to higher solar-to-electric PCE of DSCs, as set forth below in Example 3.

In certain embodiments, this invention relates to the DSCs comprising the aggregate particles of TiO₂ or ZnO nanomaterials as the photoelectrode materials.

The related dyes, electrolytes, and cathodes used to fabricate DSCs that incorporate the aggregates provided herein as a photoelectrode and/or light-scattering layer, are known to those of skill in the art.

In certain embodiments, a first aggregate layer is a photoelectrode of a solar cell.

In certain embodiments, the substrate is an anode of a solar cell.

In certain embodiments, the anode is fluorine-doped tin oxide.

In certain embodiments, the solar cell is a dye-sensitized solar cell.

In certain embodiments, the method further comprises adsorbing a photosensitizer dye on the first aggregate layer.

In certain embodiments, the method further comprises providing a cathode and a liquid electrolyte, wherein the liquid electrolyte is intermediate the cathode and the first aggregate layer adsorbed with the photosensitizer dye to provide a dye-sensitized solar cell.

In certain embodiments, the first aggregate layer is an aggregate light-scattering layer of a solar cell.

In certain embodiments, the aggregate light-scattering layer provides enhanced light scattering compared to a non-aggregate light-scattering layer formed from the first nanomaterial in non-aggregated particle form.

In certain embodiments, the polymeric additive controls a property of the aggregate particles selected from the group consisting of pore size and pore volume.

In certain embodiments, the polymeric additive is a polymer nanosphere.

In certain embodiments, the liquid is a solvent for the first nanomaterial.

In certain embodiments, the solvent chemically modifies a surface of the first nanomaterials.

In one aspect, aggregate particles prepared by the embodiments of the methods provided herein are provided.

In one aspect, a layer comprising the aggregate particles is provided.

In one aspect, a solar cell comprising the layer of aggregates as a photoelectrode is provided.

In one aspect, aggregate particles comprising zinc oxide nanomaterials in a shape selected from the group consisting of nanowires, nanorods, and nanotubes are provided.

The following examples are illustrative and not intended to be limiting.

### EXAMPLES

### Example 1

### Fabrication of Aggregate Particles of TiO₂ Nanoparticles

This example describes a general procedure for producing the aggregate particles of TiO₂ nanoparticles by an electrospray method using commercial nanoparticles denoted as P25 available from Evonik-Degussa. P25 consists of a mixed phase of anatase and rutile in the ratio of ca 4:1.

1 g of P25 TiO₂ nanoparticles was dispersed in 10 ml of solvent comprising a mixture of ethanol and water in the ratio of 1:1 by volume. After an ultrasonic treatment for 30 min, 0.1 g of PVP (MW≈1.3×106) was added to the dispersion and stirred vigorously until a homogeneous colloidal dispersion was formed. The resulting polymer-containing colloidal dispersion was electrosprayed with a flow rate of 0.3 ml/h to form aggregate particles of TiO₂ nanoparticles. The distance between the needle tip and the grounded substrate was kept at approximately 15 cm and the DC voltage between them was 12 kV. The aggregate particles were collected on aluminum foil and further dried at 100° C. in air for 2 h. The resulting aggregate particles, or P25 nanoparticles, were dispersed in a solvent such as ethanol or α-terpineol, deposited on the fluorine-doped tin oxide (FTO) glass substrates by a drop-cast method or screen-printing, and annealed at elevated temperatures to form photoelectrodes films.

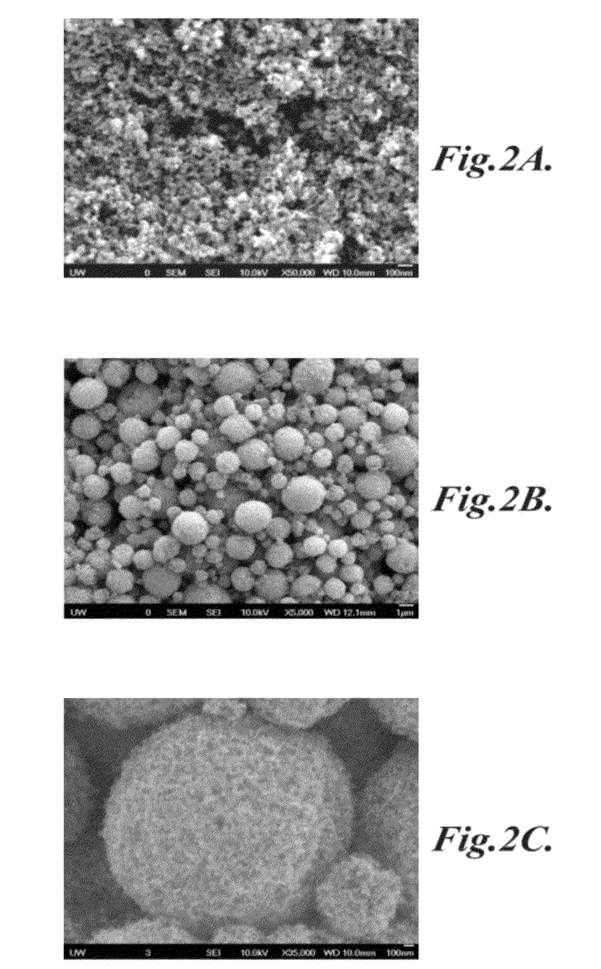

FIGS. 2A to 2C shows the SEM images of the films formed on FTO glass substrates annealed at 450° C. comprising: FIG. 2A, P25 TiO₂ nanocrystallites;

FIG. 2B, aggregate particles of P25 TiO₂ nanocrystallites produced by an electrospray method; and FIG. 2C, a single aggregate particle at a higher magnification, with a bar scale of 100 nm. The TiO₂ nanocrystallites of ˜20 nm in diameter formed a film of random mesoporous structure comprising the randomly dispersed nanoparticles. The film of TiO₂ aggregate particles comprises the polydisperse spherical aggregates of 0.4-3 μm in diameter. The film of aggregate particles was not close-packed, resulting in many large voids in the film. The high-resolution SEM image of FIG. 2C indicates that the TiO₂ aggregate particles have a rough surface and comprise numerous TiO₂ nanoparticles of approximately 20 nm in diameter which are connected to each other.

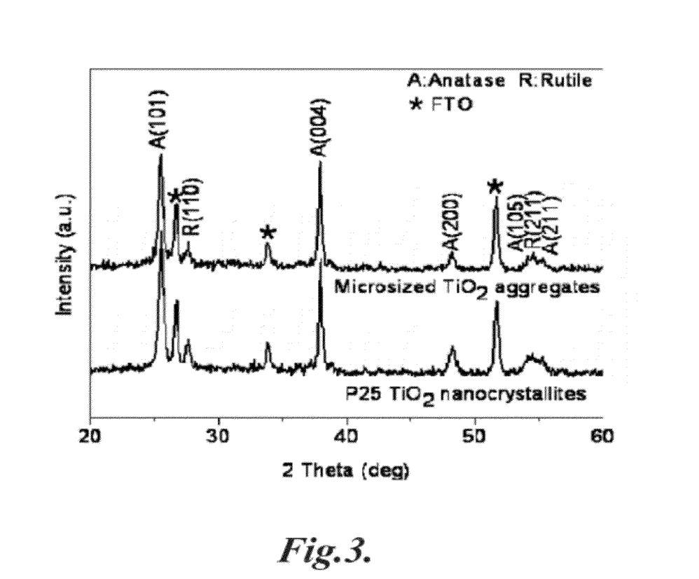

FIG. 3 shows the X-ray diffraction (XRD) patterns of TiO₂ films on the FTO glass substrates annealed at 450° C. An XRD pattern of P25 TiO₂ nanocrystallites and that of aggregate particles of P25 TiO₂ nanocrystallites produced by an electrospray method are shown in this figure. These XRD patterns reveal that both of these two kinds of films possess nearly identical patterns, indicating the presence of highly crystallized anatase and rutile phases. This is the indication that the electrospray and subsequent drying and annealing process did not cause any detectable change in the crystallinity and crystalline phases of the constituent TiO₂ nanoparticles, although there is a noticeable difference between the morphology of the films.

Table 1 compares the Brunauer-Emmett-Teller (BET) surface area and pore volume of the films annealed on the FTO glass substrates at 450° C. Samples comprising P25 TiO₂ nanocrystallites and aggregate particles comprising P25 are shown in Table 1. The specific surface area was found to be almost the same: 55 and 52 m²/g for the aggregate particles and individually dispersed nanoparticles, respectively. The pore volume of TiO₂ aggregate particles was 0.383 cc/g, which was 1.7 times that of P25 nanocrystallites.

TABLE 1
BET surface area and pore volume of P25 TiO₂ nanocrystallites
and aggregate particles comprising P25

| | | Pore |
|---|---|---|
| Sample | BET Surface Area (m²g⁻¹) | Volume (cc/g) |
| P25 TiO₂ nanocrystallites | 52 | 0.220 |
| Aggregate particles of P25 | 55 | 0.383 |

### Example 2

### Polystyrene-Mediated Synthesis of TiO₂ Aggregate Particles

In this example, polystyrene latex spheres were employed to enlarge the pore size of TiO₂ aggregate particles. Polystyrene latex spheres (diameter 50 nm) were added into the dispersion of P25 containing a polymer additive such as PVP to fabricate TiO₂ aggregate particles by an electrospray method.

1 g of P25 TiO₂ nanoparticles and 0.5 ml of aqueous solution comprising 2.5 wt % polystyrene latex spheres was dispersed in 10 ml of the mixed ethanol-water solvent (1:1 by volume). After an ultrasonic treatment for 30 min, 0.1 g of PVP (MW≈1.3×10⁶) was added and stirred vigorously until a homogeneous colloidal dispersion was formed. The polystyrene-TiO₂ colloidal dispersion was electrosprayed with a flow rate of 0.3 ml/h to form aggregate particles comprising polystyrene and TiO₂ nanoparticles. The distance between the needle tip and the grounded substrate was kept at approximately 15 cm and the DC voltage between them was 12 kV. The aggregate particles were collected on aluminum foil and dried at 100° C. in air for 2 h for further use.

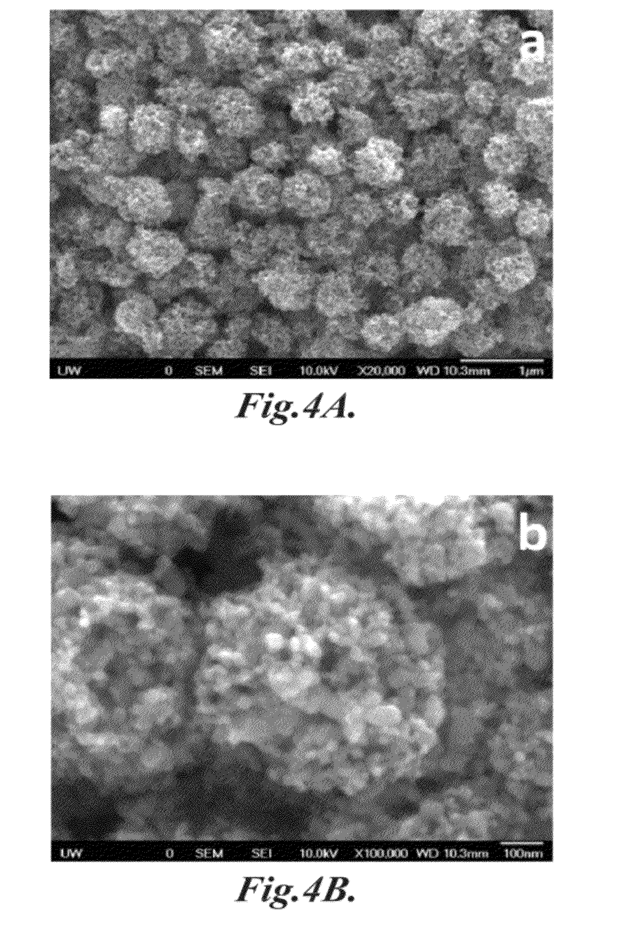

FIGS. 4A and 4B show SEM images of porous TiO₂ aggregate particles, annealed on the FTO glass substrates at 450° C., prepared with a mixture of P25 TiO₂ nanocrystallites and polystyrene nanoparticles by an electrospray method; FIG. 4A is a low magnification image; and FIG. 4B is a high magnification image. A very rough surface can be observed for these aggregate particles. The size of the aggregate particles is in the submicrometer scale, which is comparable to the wavelength of visible light. Thus, these particles will function as effective light scattering particles.

### Example 3

### Mixtures of TiO₂ Aggregate Particles and Nanoparticles

Photoelectrode films of aggregate particles comprise many gaps between aggregate particles. Filling out these gaps with nanoparticles will increase the surface area per unit volume of photoelectrode, leading to higher solar-to-electric PCE of DSCs.

In this example, mixtures of TiO₂ aggregate particles and nanoparticles were utilized to produce photoelectrode films. Six samples comprising TiO₂ nanoparticles and aggregate particles were prepared at the aggregate particle concentration of 0, 20, 30, 40, 50, 100 wt % which are denoted as N₁A₀, N_{0.8}A_{0.2}, N_{0.7}A_{0.3}, N_{0.6}A_{0.4}, N_{0.5}A_{0.5}, and N₀A₁, respectively. These mixtures of particles were first admixed with the organic vehicle based on α-terpineol to form pastes, which pastes were then coated on the FTO glass substrates as the working electrodes via doctor blade to form films of approximately 10 μm thickness. The resulting TiO₂ films underwent a programmed heat treatment (i.e., sintering) in air first at 150° C. for 15 min and then at 450° C. for 2 h.

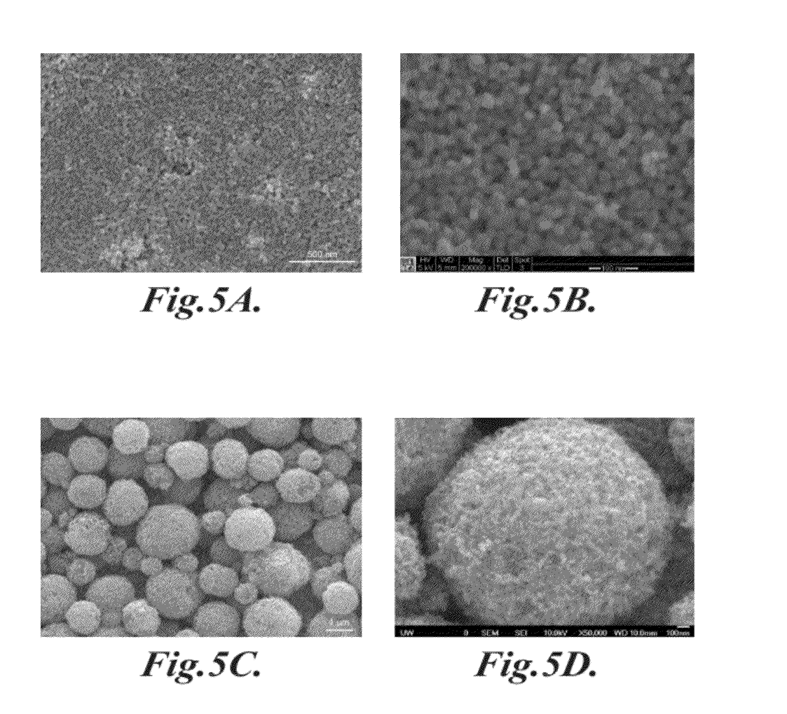

FIGS. 5A to 5D show SEM images of: FIGS. 5A and 5B, films of TiO₂ nanocrystallites (sample N₁A₀); and FIGS. 5C and 5D, films of TiO₂ aggregate particles produced by an electrospray method (sample N₀A₁). All films (FIGS. 5A to 5D) were annealed at 450° C. N₁A₀ is a mesoporous film formed from TiO₂ nanoparticles of ˜20 nm in diameter (seen in FIG. 4B). N₀A₁ comprises the polydisperse spherical aggregate particles of 0.3-2.5 μm in diameter produced by an electrospray method. TiO₂ aggregate particles were formed by assembling numerous TiO₂ nanoparticles of ˜20 nm in diameter. A rough surface on these aggregate particles can be observed from the high-magnification image of FIG. 2C, indicating highly porous structures. Meanwhile, large voids can be found in the films comprising TiO₂ aggregate particles compared to the films comprising TiO₂ nanocrystallites.

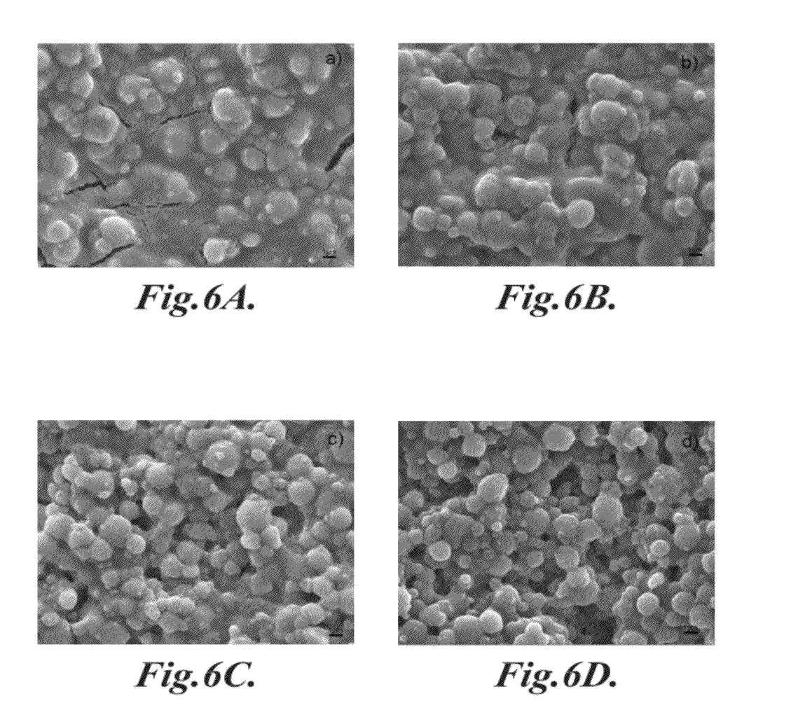

FIGS. 6A to 6D show SEM images of films after annealing at 450° C. comprising the mixtures of TiO₂ nanoparticles and aggregate particles of TiO₂ nanoparticles produced by an electrospray method: FIG. 6A N_{0.8}A_{0.2}; FIG. 6B N_{0.7}A_{0.3}; FIG. 6C N_{0.6}A_{0.4}; and FIG. 6A N_{0.5}A_{0.5}. Films from N_{0.8}A_{0.2} and N_{0.7}A_{0.3} were compact (FIGS. 6A and 6B). It can be seen that the aggregates and the nanocrystallites are mixed homogeneously in the films and there are few large void space in the films. Relatively large amount of nanocrystallites were introduced in the sample N_{0.8}A_{0.2}, resulting in the formation of cracks on the surface of the film which may adversely affect the connectivity of the particles in the whole film. Large voids were obviously observed in the films from N_{0.6}A_{0.4} and N_{0.5}A_{0.5} due to the increased concentration of aggregate particles.

### Example 4

### Hollow Structured TiO₂ Aggregate Particles

This example presents the fabrication of hollow structured TiO₂ aggregate particles by an electrospray method. Hollow structures of aggregates increase the dye loading possible for the aggregates, as well as the diffusion of electrolyte in DSCs, due to large voids in the aggregates.

The experimental setup used for fabricating this structure employed a spinneret consisting of two coaxial needles, through which mineral oil and the polymer-containing TiO₂ colloidal dispersion were ejected to form a compound jet.

1 g of P25 TiO₂ nanoparticles was dispersed in 10 ml of the mixed ethanol-water solvent (1:1 by volume). After an ultrasonic treatment for 30 min, 0.1 g PVP (MW≈1.3×10⁶) was added to the dispersion and the resulting dispersion was stirred vigorously until a homogeneous colloidal dispersion was obtained. The resulting polymer-containing TiO₂ colloidal dispersion as the shell fluid was electrosprayed with a flow rate of 0.6 ml/h together with the mineral oil as the core fluid. The flow rate of the core fluid was 0.1 ml/h. The distance between the needle tip and the grounded substrate was kept at approximately 15 cm and the DC voltage between them was 24 kV. The aggregates were collected on aluminum foil and dried at 100° C. in air for 2 hr for further use.

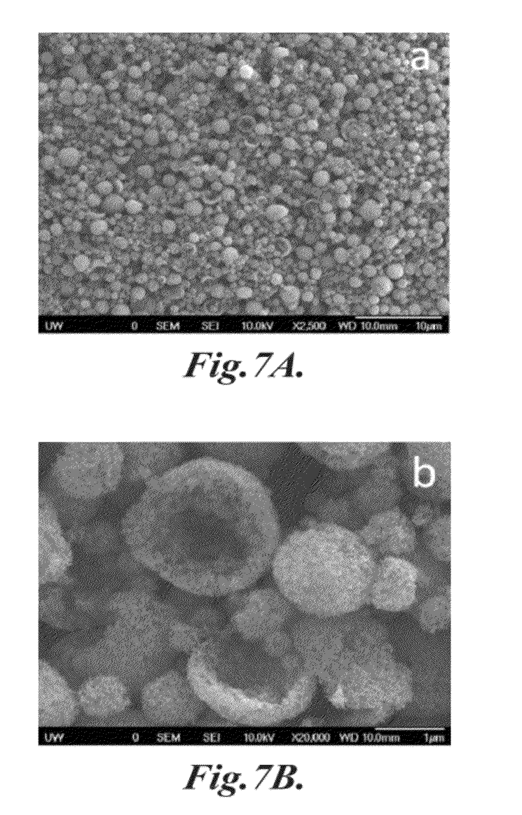

FIGS. 7A and 7B show SEM images of hollow aggregate particles of TiO₂ nanoparticles produced by an electrospray method: FIG. 7A under low magnification; and FIG. 7B under high magnification.

### Example 5

### Controlling the Structures of TiO₂ Aggregate Particles by Adjusting the Synthesis Conditions

This example demonstrates the impact of either the recipe of the precursor solutions of electrospray method or the fabrication parameters on the morphology of TiO₂ aggregate particles.

By controlling aggregate size and size distribution, packing of aggregates in a film can be optimized. One exemplary benefit of a closely-packed film of aggregates is higher power conversion efficiency in solar cells formed using the aggregate films.

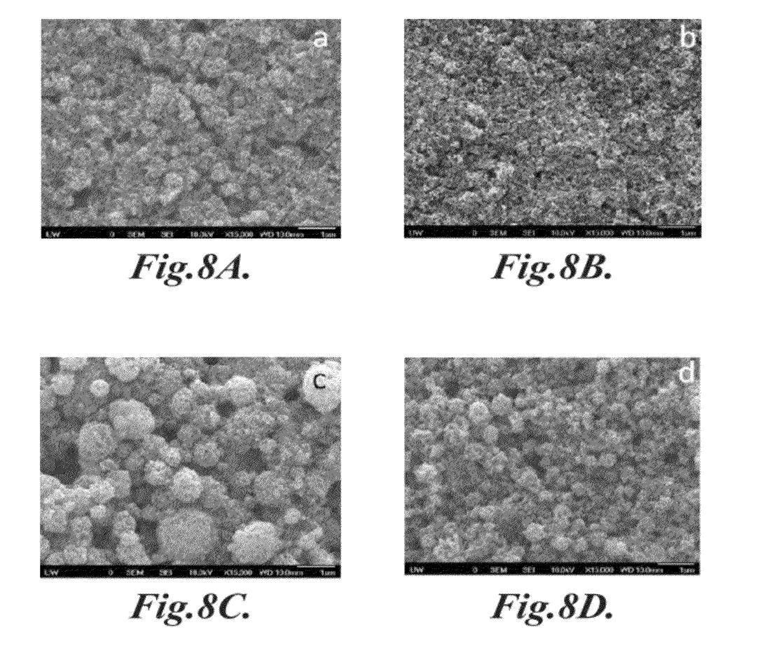

Specifically, the influence of different polymer additives, the high voltage between the nozzle and collector, and the ejection speed of the precursor solution was studied. These results are shown in FIGS. 8, 9, and 10.

FIGS. 8A to 8D show SEM images of aggregate particles of TiO₂ nanoparticles with different polymer additives produced by an electro spray method: FIG. 8A, PEG (M_{w}≈2×10⁴); FIG. 8B, PEG (M_{w}≈400); FIG. 8C, PVP (M_{w}≈1.3×10⁶); and FIG. 8D, PVP (M_{w}≈5.5×10⁴).

FIGS. 9A to 9C show SEM images of aggregate particles of TiO₂ nanoparticles prepared by an electrospray method under different voltages across a distance of 15 cm: FIG. 9A, 6 kV; FIG. 9B, 10 kV; and FIG. 9C, 14 kV.

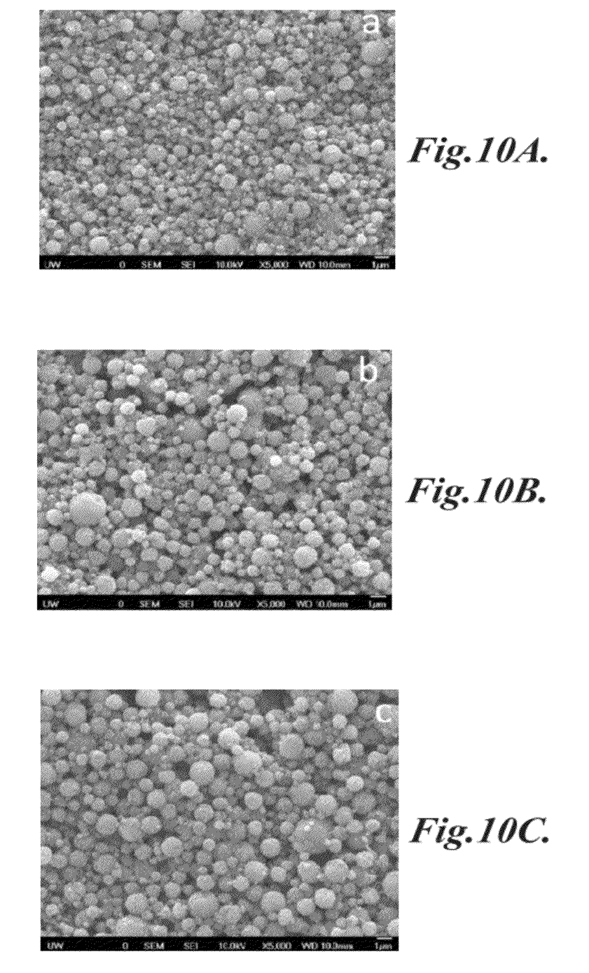

FIGS. 10A to 10C shows the SEM images of aggregate particles of TiO₂ nanoparticles prepared by an electrospray method with different ejection speed: FIG. 10A, 0.1 ml/h; FIG. 10B, 0.2 ml/h; and FIG. 10C, 0.3 ml/h.

### Example 6

### Aggregate Particles of ZnO Nanowires

Electrospray was also used for producing aggregates comprising ZnO nanowires. Using nanowires or nanorods or nanotubes, instead of equal-axis nanoparticles produces more open porous structures in the resulting aggregates, which can benefit charge transfer and/or charge transport.

The fabrication of aggregate particles of ZnO nanowires starts from a chemical solution synthesis of ZnO nanowires. A solution of 0.01 M zinc acetate in ethanol was prepared and heated at 60° C. for 1 hr. To this solution, 0.03 M potassium hydroxide (KOH) in ethanol was added dropwise. The solution was initially cloudy, turned to clear, and became cloudy again after stirring for 3-4 hours. Part of the solvent was evaporated by a subsequent heating at 60° C. for up to 24 hours. As-received ZnO concentrated solution was then poured into a diethylene glycol solution that contained 0.0005 M zinc acetate at 160° C. The resulting mixture solution was kept stirring for another 2 hours to form ZnO nanowires. Finally, ZnO nanowires were separated from the solution by a centrifuge method.

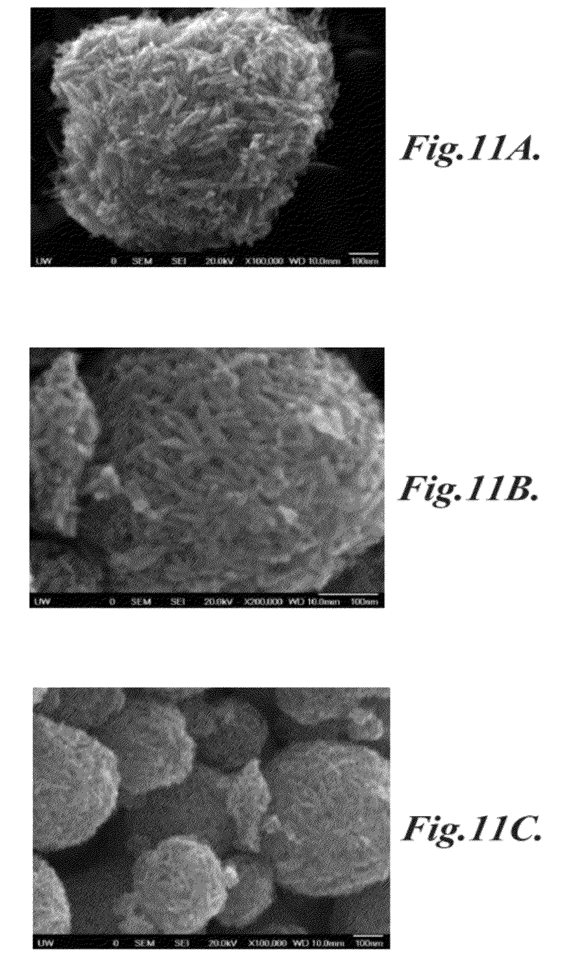

The dispersion of ZnO nanowires used for electrospray comprised 0.13 g of ZnO nanowire powder and a mixture of 0.5 mL ethanol and 0.5 mL water. For the fabrication of aggregate particles, an ejection speed of 0.15 mL/h and 14-15 kV high voltage were adopted. The distance from the nozzle to collector was about 18 cm. FIGS. 11A to 11C show SEM images of the aggregate particles of ZnO nanowires prepared by an electrospray method.

### Example 7

### Pyrolysis Fabrication of Aggregate Particles

Pyrolysis fabrication is a method based on the generation of aerosol droplets via sonication or pneumatic force followed by a rapid evaporation of the solvent at elevated temperatures (˜500-800° C.) to form an aggregate structure comprising nanomaterials. The precursor solutions for the electrospray methods mentioned in Examples 1, 2, 5 and 6 can also be utilized in the production of TiO₂ or ZnO aggregate particles by pyrolysis with sonication or pneumatic force. Pyrolysis offers low processing cost and higher productivity.

### Example 8

### Photoelectrodes of Double-Layer Structures Comprising Aggregate Particles and Nanoparticles

All of the TiO₂ and ZnO aggregate particles in Examples 1, 2, 4, 5 and 6 can be used to form a light scattering layer in the photoelectrode film of DSCs. Use of TiO2 aggregate particles as light-scattering layer has resulted in an enhancement in the conversion efficiency of dye-sensitized solar cells, typically, from 6.5% to 8.8%.

The advantage of a light-scattering layer comprising aggregate particles is that the resulting photoelectrode film possesses a large internal surface area while providing the function of effective light scattering, leading to enhanced light absorption by DSCs and thus contributing to power conversion efficiency.

### Example 9

### DSCs Comprising the TiO₂ Aggregate Particles Prepared by the Electrospray Method

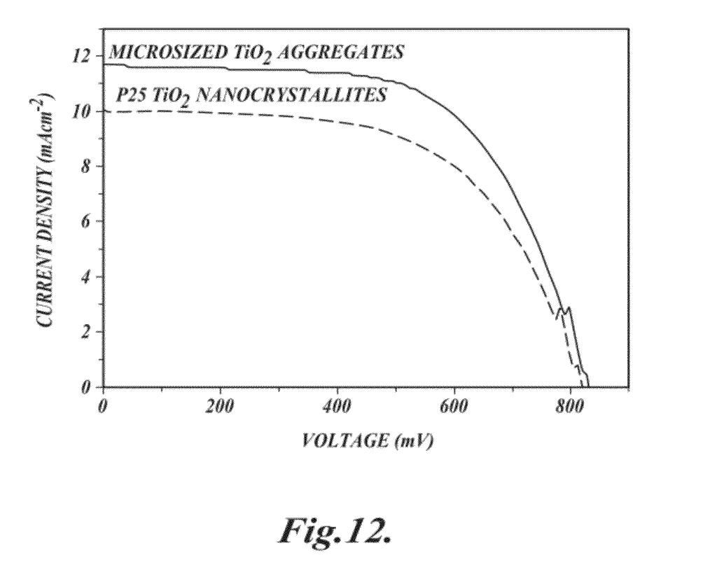

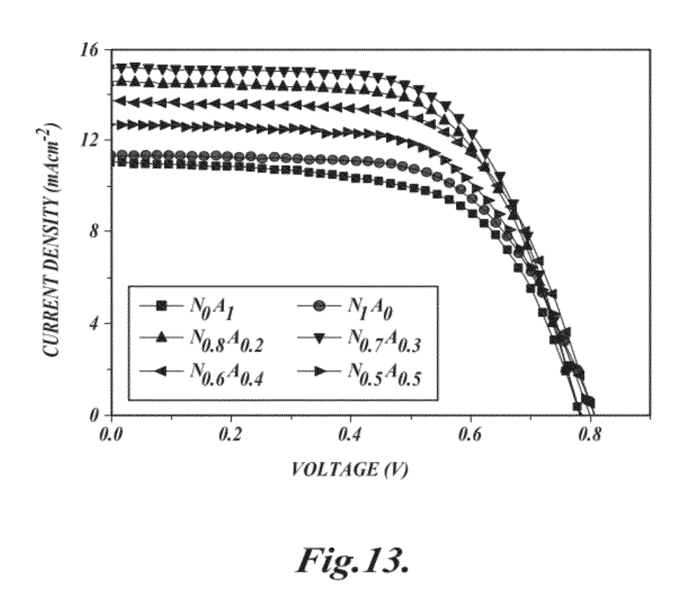

The TiO₂ aggregate particles prepared with the electrospray method exhibit an enhancement in the solar-to-electric PCE DSCs. FIG. 12 shows the current-voltage (1-V) curve of a DSC with the photoelectrode comprising the aggregate particles of TiO₂ nanoparticles prepared by an electrospray method and the I-V curve of a DSC with the photoelectrode comprising P25 TiO₂ nanoparticles. FIG. 13 shows the I-V curves of DSCs with the photoelectrodes comprising N₁A₀, N_{0.8}A_{0.2}, N_{0.7}A_{0.3}, N_{0.6}A_{0.4}, N_{0.5}A_{0.5}, and N₀A₁ samples of Example 3.

Table 2 shows the open-circuit voltage (V_{OC}), short-circuit current density (I_{SC}), fill factor (FF), and solar-to-electric PCE (η) of DSCs comprising P25 TiO₂ nanocrystallites and aggregate particles of P25. DSCs were assembled following a standard protocol. The anode of DSC was a FTO glass substrate comprising a photoelectrode film of ˜5-15 μm thickness on which a photosensitizer dye such as N3 or cis-bis(isothiocyanate)-bis-(2,2′-bipyridyl-4,4′dicarboxylate)ruthenium(II)bis(tetrabutylammonium) (N719) was adsorbed. The counter electrode was a platinum-coated silicon wafer or platinum-coated FTO glass substrate. The distance between these two electrodes was approximately 40 μm. Finally, a liquid electrolyte was introduced into the space between these two electrodes to form a DSC.

Table 3 shows V_{OC}, I_{SC}, FF, and η of the DSCs comprising the photoelectrodes made from the samples N₁A₀, N_{0.8}A_{0.2}, N_{0.7}A_{0.3}, N_{0.6}A_{0.4}, N_{0.5}A_{0.5}, and N₀A₁ of EXAMPLE 3.

TABLE 2
Properties of DSCs comprising the photoelectrode made of
P25 TiO₂ nanocrystallites and the photoelectrode made
of the aggregate particles of P25

| Photoelectrode material | V_{oc} (mV) | I_{sc} (mA/cm²) | FF | η (%) |
|---|---|---|---|---|
| P25 TiO₂ | 820 | 10.05 | 0.584 | 4.8 |
| nanocrystallites | | | | |
| Aggregate particles of | 830 | 11.67 | 0.609 | 5.9 |
| P25 | | | | |

TABLE 3
V_{oc}, I_{sc}, FF, and η of DSCs comprising N₁A₀, N_{0.8}A_{0.2}, N_{0.7}A_{0.3},
N_{0.6}A_{0.4}, N_{0.5}A_{0.5}, and N₀A₁ of EXAMPLE 3 as the
photoelectrode material.

| Photoelectrode | | | | |
|---|---|---|---|---|
| material | V_{oc} (V) | I_{sc} (mA/cm²) | FF | η (%) |
| N₁A₀ | 0.807 | 11.36 | 0.628 | 5.76 |
| N_{0.8}A_{0.2} | 0.781 | 14.56 | 0.631 | 7.18 |
| N_{0.7}A_{0.3} | 0.781 | 15.21 | 0.635 | 7.54 |
| N_{0.6}A_{0.4} | 0.801 | 13.70 | 0.632 | 6.94 |
| N_{0.5}A_{0.5} | 0.799 | 12.70 | 0.611 | 6.20 |
| N₀A₁ | 0.783 | 11.06 | 0.617 | 5.34 |

In FIG. 12 and Table 2, the aggregate particles of P25 TiO₂ nanoparticles show an efficiency of 5.9%, higher than the efficiency of 4.8% exhibited by P25 TiO₂ nanoparticles. In FIG. 13 and Table 3, the sample N₀₇A₀₃ comprising 70 wt % nanoparticles and 30 wt % aggregate particles shows the solar-to-electric PCE of approximately 7.5%.

1. A method of forming aggregate particles of a first nanomaterial, comprising:
(a) forming aerosol droplets of a dispersion comprising a first nanomaterial in a liquid; and
(b) removing the liquid from the droplets to form aggregate particles of the first nanomaterial.

2. The method of claim 1, wherein the liquid comprises a polymeric additive.

3. The method of claim 2, wherein the polymeric additive is incorporated into the aggregate particles upon removal of the liquid; and wherein the polymeric additive is removed from the aggregate particles by annealing the aggregate particles.

4. The method of claim 2, wherein the polymeric additive controls a property of the aggregate particles selected from the group consisting of pore size and pore volume.

5. The method of claim 1, wherein the liquid chemically modifies a surface of the first nanomaterials.

6. The method of claim 1, wherein forming aerosol droplets comprises applying a force to the dispersion selected from the group consisting of an electrostatic force, a pneumatic force, sonication, and combinations thereof.

7. The method of claim 1, wherein the first nanomaterial is comprised of a material selected from the group consisting of titanium dioxide, zinc oxide, and mixtures thereof.

8. The method of claim 1, wherein the first nanomaterial is selected from the group consisting of a nanotube, a nanoparticle, a nanowire, and mixtures thereof.

9. The method of claim 1, wherein the first nanomaterial comprises a crystalline structure selected from the group consisting of the anatase phase of TiO₂, the rutile phase of TiO₂, and a mixture thereof.

10. The method of claim 1, wherein the liquid is a mixture of ethanol and water.

11. A method of forming a layer of aggregate particles, comprising depositing aggregate particles formed according to a method of claim 1 on a substrate to provide a first aggregate layer.

12. The method of claim 11, wherein the polymeric additive is removed from the aggregate particles by annealing the aggregate particles after the aggregate particles are deposited on the substrate.

13. The method of claim 11 further comprising depositing a second nanomaterial on the substrate, wherein the second nanomaterial is the same or different than the first nanomaterial.

14. The method of claim 11 further comprising heat treating the substrate.

15. The method of claim 11, wherein the first aggregate layer is selected from the group consisting of a photoelectrode of a solar cell and an anode of a solar cell.

16. The method of claim 11 further comprising adsorbing a photosensitizer dye on the first aggregate layer.

17. The method of claim 16 further comprising providing a cathode and a liquid electrolyte, wherein the liquid electrolyte is intermediate the cathode and the first aggregate layer adsorbed with the photosensitizer dye to provide a dye-sensitized solar cell.

18. The method of claim 11, wherein the first aggregate layer is an aggregate light-scattering layer of a solar cell.

19. The method of claim 18, wherein the aggregate light-scattering layer provides enhanced light scattering compared to a non-aggregate light-scattering layer formed from the first nanomaterial in non-aggregated particle form.

20. Aggregate particles comprising zinc oxide nanomaterials in a shape selected from the group consisting of nanowires, nanorods, and nanotubes.
